(19) United States
(12) Patent Application Publication
(10) Pub. No.: US 2024/0223186 A1
(43) Pub. Date: Jul. 4, 2024

(54) DRIVING SYSTEM FOR SWITCHING DEVICE

(71) Applicant: Delta Electronics (Shanghai) Co., Ltd., Shanghai (CN)

(72) Inventors: Yuesen Guo, Shanghai (CN); Kai Dong, Shanghai (CN); Chang Xu, Shanghai (CN)

(21) Appl. No.: 18/533,161

(22) Filed: Dec. 7, 2023

(30) Foreign Application Priority Data
Jan. 3, 2023 (CN) 202310003679.9

(51) Int. Cl. H03K 17/76; H01L 29/866

(52) U.S. Cl. CPC H03K 17/76; H01L 29/866; H03K 2217/0081

(57) ABSTRACT

The present disclosure provides a driving system for driving a switching device and including a switch driving module and corresponding a switching device. The switch driving module receives a driving signal and outputs a driving voltage. The switching device is electrically coupled to the switch driving module, the switching device receives the driving voltage and is turned on or off accordingly. The switch driving module includes a high-impedance voltage dividing module and a constant voltage dividing module. The high-impedance voltage dividing module is configured for dividing and limiting the driving voltage of the switching device when the switching device is turned on. The constant voltage dividing module provides a low-impedance shunt path for the gate-source of the switching device when the switching device is turned off and the changing rate of a drain-source voltage of the switching device is too high.

### CROSS-REFERENCE TO RELATED APPLICATION

This application claims priority to China Patent Application No. 202310003679.9, filed on Jan. 3, 2023, the entire contents of which are incorporated herein by reference for all purposes.

### FIELD OF THE INVENTION

The present disclosure relates to a driving system for a switching device, and more particularly to a driving system capable of controlling the gate-source voltage of a switching device.

### BACKGROUND OF THE INVENTION

Gallium nitride (GaN) device has advantages of small on-resistance, small driving loss, fast switching speed, good temperature characteristics and high power density compared to the general switching device. Therefore, GaN device has become the focus in the field of the switching converters. However, the characteristics of GaN device led to problems such as low gate-source driving threshold voltage, low upper limit of gate-source voltage and parasitic parameters sensitive to high slew rates. Accordingly, the application of GaN device in high-frequency power topology is limited.

The driving threshold voltage of the gate-source of the existing GaN device is lower than that of the conventional switching device. When the drain-source of the GaN device has a high slew rate, a peak voltage is generated at the gate-source through a Miller capacitance. False trigger of the switching device occurs when the mentioned peak voltage exceeds the driving threshold voltage of the gate-source of the GaN device. In addition, in a bridge switching circuit with GaN device, the reverse conduction of the lower transistor will make the bootstrap voltage high, which may lead to problems such as clamping failure of the upper transistor driving circuit. The reverse conduction loss is increased due to the excessive turn-off negative voltage.

Therefore, there is a need of providing a driving system for switching device to obviate the drawbacks encountered from the prior arts.

### SUMMARY OF THE INVENTION

It is an object of the present disclosure to provide a driving system for switching device. In the driving system, the high-impedance voltage dividing module performs voltage division and limiting on the driving voltage of the switching device when the switching device is turned on, thereby making the gate-source voltage of the switching device to be lower than the clamping voltage value. In addition, the constant voltage dividing module of the present disclosure provides a low-impedance shunt path for the gate-source of the switching device when the change rate of the drain-source voltage of the switching device is too high. Accordingly, the gate-source voltage of the switching device is controlled to be lower than the trigger threshold so that the false trigger of the switching device is avoided.

In accordance with an aspect of the present disclosure, there is provided a driving system for driving at least one switching device. The driving system includes at least one switch driving module and corresponding at least one switching device. The switch driving module receives a driving signal and outputs a driving voltage according to the driving signal. The switching device is electrically coupled to the switch driving module, the switching device receives the driving voltage, and the switching device is turned on or off according to the driving voltage. The switch driving module includes a high-impedance voltage dividing module and a constant voltage dividing module. The high-impedance voltage dividing module is configured for dividing and limiting the driving voltage of the switching device when the switching device is turned on, thereby making a gate-source voltage of the switching device to be lower than a clamping voltage value. The constant voltage dividing module is electrically coupled to the high-impedance voltage dividing module. When the switching device is turned off and the changing rate of a drain-source voltage of the switching device is too high, the constant voltage dividing module provides a low-impedance shunt path for the gate-source of the switching device to make the gate-source voltage of the switching device to be lower than a trigger threshold.

In accordance with an aspect of the present disclosure, there is provided a driving system for driving at least one switching device. The driving system includes at least one switch driving module and corresponding at least one switching device. The switch driving module receives a driving signal and outputs a driving voltage according to the driving signal. The switching device is electrically coupled to the switch driving module, the switching device receives the driving voltage, and the switching device is turned on or off according to the driving voltage. The switch driving module includes a high-impedance voltage dividing module and a constant voltage dividing module. The high-impedance voltage dividing module is configured for dividing and limiting the driving voltage of the switching device when the switching device is turned on, thereby making a gate-source voltage of the switching device to be lower than a clamping voltage value. The constant voltage dividing module is electrically coupled to the high-impedance voltage dividing module. When the switching device is turned off, the constant voltage dividing module clamps the gate-source voltage of the switching device to a low constant negative voltage value for providing a turn-off path for the switching device and reducing the reverse conduction voltage of the switching device.

The above contents of the present invention will become more readily apparent to those ordinarily skilled in the art after reviewing the following detailed description and accompanying drawings, in which:

### BRIEF DESCRIPTION OF THE DRAWINGS

FIG. 1 is a schematic block diagram illustrating a driving system for switching device according to an embodiment of the present disclosure;

FIG. 2 is a schematic block diagram illustrating a driving system for switching device according to another embodiment of the present disclosure;

FIG. 3 is a schematic circuit diagram illustrating a driving system for switching device of FIG. 2 applied to a driving circuit for GaN device;

FIG. 4 is a schematic circuit diagram illustrating a driving system for switching device applied to a driving circuit for GaN device according to another embodiment of the present disclosure; and

FIG. 5 schematically shows the waveforms of the voltage of the driving circuit for GaN device of FIG. 3.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed.

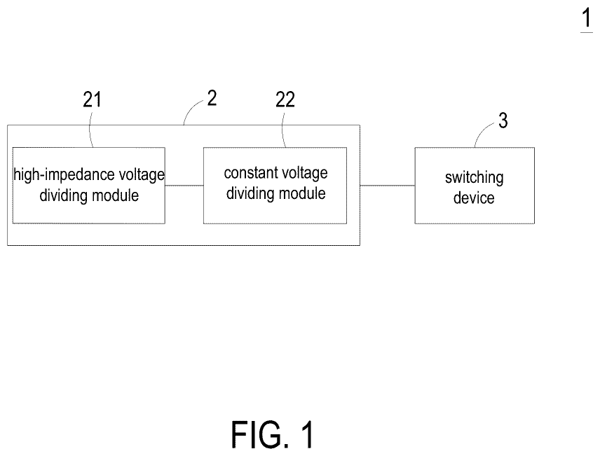

FIG. 1 is a schematic block diagram illustrating a driving system for driving at least one switching device according to an embodiment of the present disclosure. As shown in FIG. 1, the driving system 1 includes at least one switch driving module 2 and corresponding at least one switching device 3. The switch driving module 2 receives a driving signal and outputs a driving voltage according to the driving signal. The switching device 3 is electrically coupled to the switch driving module 2. The switching device 3 receives the driving voltage, and the switching device 3 is turned on or off according to the driving voltage. In an embodiment, the switching device 3 is a GaN device. The switch driving module 2 includes a high-impedance voltage dividing module 21 and a constant voltage dividing module 22. The high-impedance voltage dividing module 21 is configured for dividing and limiting the driving voltage of the switching device 3 when the switching device 3 is turned on, thereby making the gate-source voltage of the switching device 3 to be lower than a clamping voltage value. The constant voltage dividing module 22 is electrically coupled to the high-impedance voltage dividing module 21. When the switching device 3 is turned off and the changing rate of the drain-source voltage of the switching device 3 is too high, the constant voltage dividing module 22 provides a low-impedance shunt path for the gate-source of the switching device 3 to make the gate-source voltage of the switching device 3 to be lower than a trigger threshold.

In the driving system 1 for the switching device of the present disclosure, the high-impedance voltage dividing module performs voltage division and limiting on the driving voltage of the switching device when the switching device is turned on, thereby making the gate-source voltage of the switching device to be lower than the clamping voltage value. In addition, the constant voltage dividing module of the present disclosure provides a low-impedance shunt path for the gate-source of the switching device when the change rate of the drain-source voltage of the switching device is too high. Accordingly, the gate-source voltage of the switching device is controlled to be lower than the trigger threshold so that the false trigger of the switching device is avoided.

In an embodiment, when the switching device 3 is turned off, the constant voltage dividing module 22 clamps the gate-source driving voltage of the switching device 3 to a low constant negative voltage value for providing a turn-off path for the switching device 3 and reducing the reverse conduction voltage of the switching device 3. In an embodiment, the driving system 1 includes two switching devices 3, the two switching devices 3 are electrically coupled in series to form a half-bridge switching circuit.

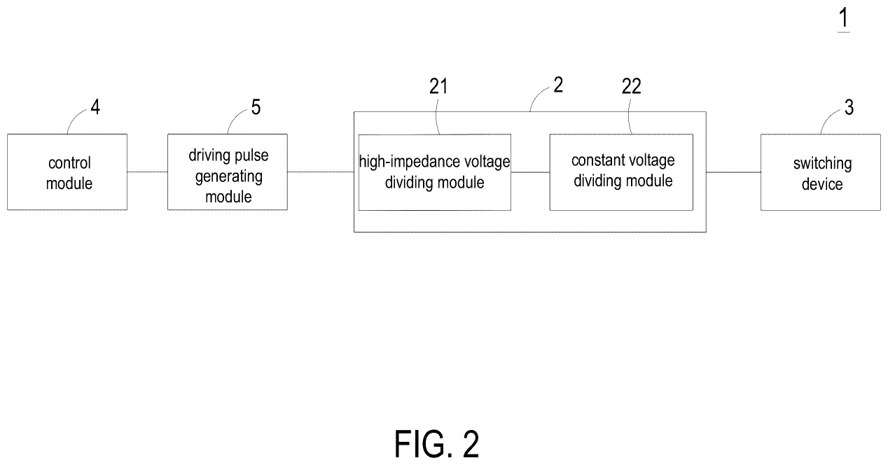

FIG. 2 is a schematic block diagram illustrating a driving system for switching device according to another embodiment of the present disclosure. The elements of FIG. 2 that are similar with those of FIG. 1 are represented by the same reference numerals, and the detailed description thereof is omitted herein. As shown in FIG. 2, in this embodiment, the driving system 1 for the switching device further includes a control module 4 and a driving pulse generating module 5. The control module 4 is configured for outputting a control signal. The driving pulse generating module 5 is electrically coupled to the control module 4 and the switch driving module 2. The driving pulse generating module 5 receives the control signal and outputs the driving signal to the switch driving module 2 according to the control signal. In an embodiment, the driving pulse generating module 5 includes a driving chip which receives the control signal and outputs the driving signal.

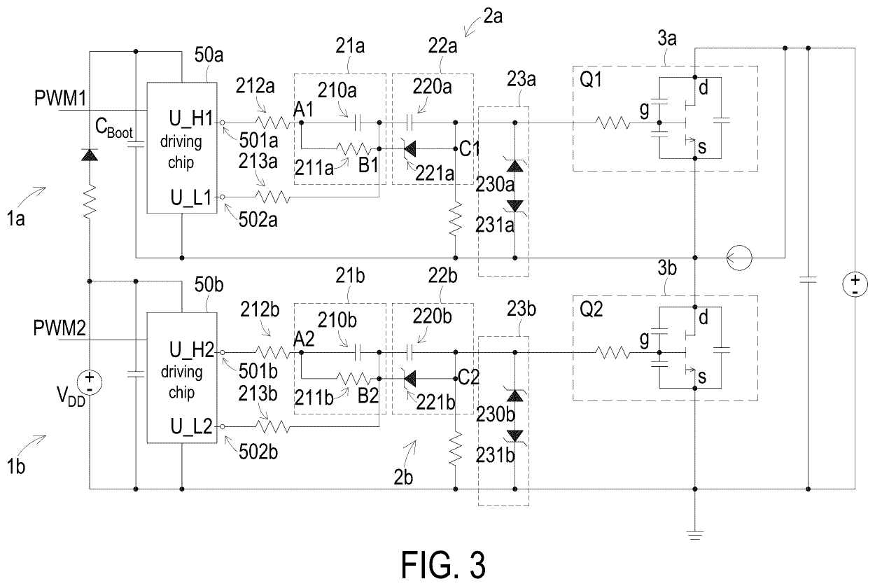

FIG. 3 is a schematic circuit diagram illustrating a driving system for switching device of FIG. 2 applied to a driving circuit for GaN device. The driving circuit for GaN device shown in FIG. 3 includes driving systems 1a and 1b for the switching devices. The structure of the driving systems 1a and 1b in FIG. 3 are the same as that of the driving system 1 shown in FIGS. 1 and 2, and the detailed descriptions thereof are omitted herein. As shown in FIG. 3, the switching device 3a of the driving system 1a includes a switch Q1, and the switching device 3b of the driving system 1b includes a switch Q2. The switches Q1 and Q2 form a half-bridge switching circuit. Since the circuit structures of the driving systems 1a and 1b for driving the switches Q1 and Q2 are the same, only the detailed circuit structure of the driving system 1a is described as follow.

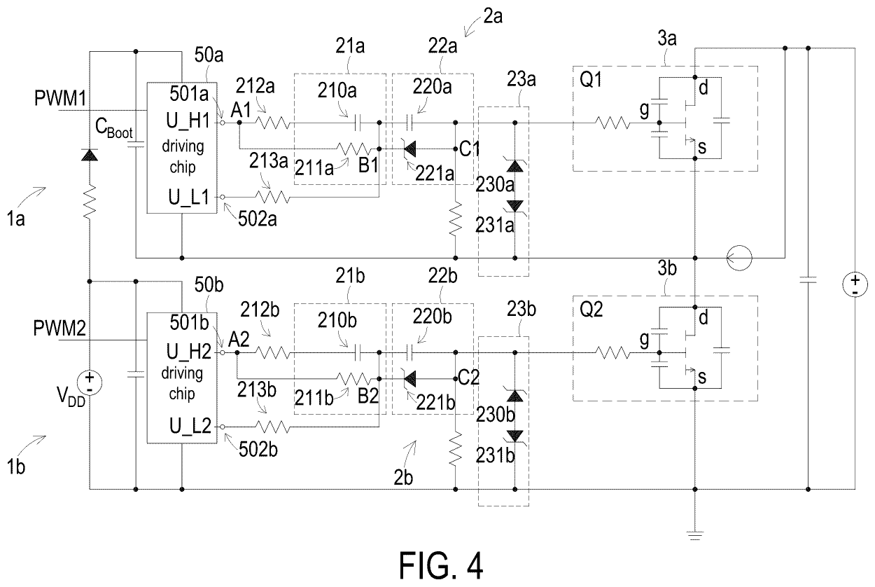

Please refer to FIGS. 2 and 3. The driving chip 50a includes two output terminals 501a and 502a, the high-impedance voltage dividing module 21a includes a first capacitor 210a and a first resistor 211a electrically coupled in parallel. A first terminal of the first capacitor 210a and a first terminal of the first resistor 211a are both electrically coupled to a first node A1. A second terminal of the first capacitor 210a and a second terminal of the first resistor 211a are both electrically coupled to a second node B1. The first node A1 and the second node B1 are electrically coupled to the output terminals 501a and 502a of the driving chip 50a through two driving resistors 212a and 213a respectively. In specific, the first node A1 is electrically coupled to a first output terminal 501a of the driving chip 50a, and the second node B1 is electrically coupled to a second output terminal 502a of the driving chip 50a. The voltage level of the first output terminal 501a is higher than that of the second output terminal 502a. In an embodiment, the first node A1 is not limited to be electrically coupled between the driving resistor 212a and the first capacitor 210a. As shown in FIG. 4, the first node A1 may be electrically coupled between the output terminal 501a of the driving chip 50a and the driving resistor 212a. In specific, a first terminal of the first capacitor 210a is electrically coupled to a first node A1 through the driving resistor 212a. The first terminal of the driving resistor 212a is electrically coupled to the first node A1, and the second terminal of the first capacitor 210a and the second terminal of the first resistor 211a are both electrically coupled to a second node B1. The first node A1 is electrically coupled to the first output terminal 501a of the driving chip 50a, and the second node B1 is electrically coupled to the second output terminal 502a of the driving chip 50a through the second driving resistor 213a. The voltage level of the first output terminal 501a is higher than that of the second output terminal 502a.

Please refer to FIGS. 2 and 3, the constant voltage dividing module 22a includes a second capacitor 220a and a first Zener diode 221a electrically coupled in parallel. A first terminal of the second capacitor 220a and a cathode of the first Zener diode 221a are electrically coupled to the high-impedance voltage dividing module 21a. A second terminal of the second capacitor 220a and an anode of the first Zener diode 221a are electrically coupled to a gate g of the switching device 3a. In an embodiment, the capacitance of the first capacitor 210a of the high-impedance voltage dividing module 21a is lower than the capacitance of the second capacitor 220a of the constant voltage dividing module 22a, thereby providing a stable voltage for the gate-source.

In an embodiment, the switch driving module 2a further includes a voltage clamping module 23a electrically coupled to the constant voltage dividing module 22a and the source s of the switching device 3a and configured for clamping the gate-source voltage of the switching device 3a. The voltage clamping module 23a includes a second Zener diode 230a and a third Zener diode 231a electrically coupled in series. The anode of the second Zener diode 230a is electrically coupled to the anode of the third Zener diode 231a. The cathode of the second Zener diode 230a is electrically coupled to a gate g of the switching device 3. The cathode of the third Zener diode 231a is electrically coupled to the source s of the switching device 3a.

The output terminals 501a and 502a of the driving system 1a output the driving pulses U_H1 and U_L1 corresponding to the driving signal PWM1 respectively. The output terminals 501b and 502b of the driving system 1b output the driving pulses U_H2 and U_L2 corresponding to the driving signal PWM2 respectively.

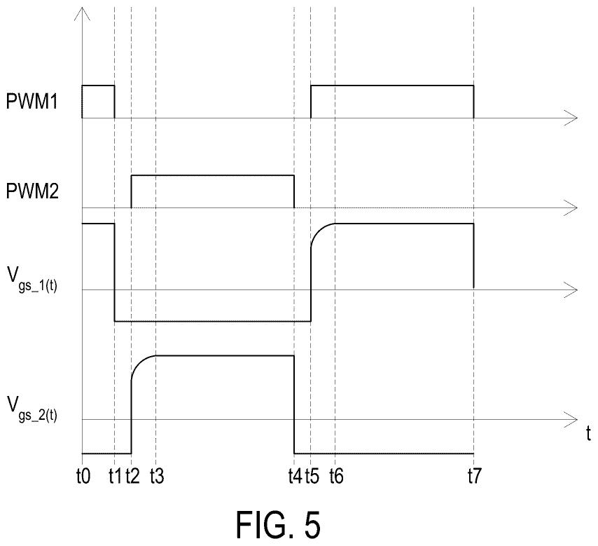

FIG. 5 schematically shows the waveforms of the voltage of the driving circuit for GaN device of FIG. 3. Please refer to FIGS. 3 and 5, the voltage waveforms of the driving signal PWM1 of the driving system 1a, the driving signal PWM2 of the driving system 1b, the gate-source voltage Vgs_1(t) of the switch Q1 and the gate-source voltage Vgs_2(t) of the switch Q2 are shown in FIG. 5. During the period from time to to t1, the driving circuit for the GaN device is in a stable state, and the switching state of the switches Q1 and Q2 remains unchanged. The switch Q1 is in an on state, and the switch Q2 is in an off state.

During the period from time t1 to t2, the driving signal PWM1 of the driving system 1a changes from high level to low level, the driving pulse U_H1 changes from high level to high impedance, and the driving pulse U_L1 changes from high impedance to low level. In this circumstance, the second capacitor 220a is electrically coupled in series with the driving resistor 213a, and the second capacitor 220a is electrically coupled in antiparallel with the gate-source of the switch Q1. Therefore, the gate-source voltage Vgs_1(t) of the switch Q1 is clamped at a low negative voltage value, and the gate-source of the switch Q1 realizes a negative voltage turn-off, and the second capacitor 220a and the driving resistor 213a are turned off in sequence. The driving signal PWM2 of the driving system 1b maintains a low level, the driving pulse U_H2 maintains a high impedance, the driving pulse U_L2 maintains a low level, and the switch Q2 remains in the off state.

During the period from time t2 to t3, the driving signal PWM1 of the driving system 1a maintains a low level, the driving pulse U_H1 maintains a high impedance, and the driving pulse U_L1 maintains a low level. The driving signal PWM2 of the driving system 1b changes from low level to high level, the driving pulse U_H2 changes from high impedance to high level, the driving pulse U_L2 changes from low level to high impedance, and the auxiliary power supply VDD provides a positive charging for the gate-source of the switch Q2. Therefore, the switch Q2 is turned on when the gate-source voltage of the switch Q2 reaches the driving threshold voltage of the switch Q2. Meanwhile, the conduction path of the switch Q2 is the driving resistor 212b, the first capacitor 210b and the second capacitor 220b in sequence. The driving resistor 212b, the first capacitor 210b and the second capacitor 220b realize a rapid voltage division for ensuring that the driving voltage of the gate-source of the switch Q2 does not exceed the clamping voltage value. Since the switch Q2 is turned on, the bootstrap capacitor CBoot is rapidly charged to store charge for the forward conduction of the switch Q1. Meanwhile, the switch Q1 remains in the off state.

During the period from time t3 to t4, the driving circuit for the GaN device is in a stable state. The switching states of the switches Q1 and Q2 are remained. The driving signal PWM1 of the driving system 1a maintains a low level, the driving pulse U_H1 maintains a high impedance, and the driving pulse U_L1 maintains a low level. The voltage of the second capacitor 220a ensures that the gate-source of the switch Q1 realizes a negative voltage turn-off, and the switch Q1 remains in the off state. The driving pulse U_H2 of the driving system 1b maintains a high level, the driving pulse U_L2 maintains a high impedance, the first resistor 211b consumes the charge stored in the first capacitor 210b, and a current flows through the driving resistor 212b, the first resistor 211b, the first Zener diode 221b, the second Zener diode 230b and the third Zener diode 231b in sequence. The switch Q2 remains in the on state.

During the period from time t4 to t5, the driving signal PWM1 of the driving system 1a maintains a low level, the driving pulse U_H1 maintains a high impedance, and the driving pulse U_L1 maintains a low level, and the switch Q1 remains in the off state. The driving signal PWM2 of the driving system 1b changes from high level to low level, the driving pulse U_H2 changes from high level to high impedance, and the driving pulse U_L2 changes from high impedance to low level. In this circumstance, the second capacitor 220b is electrically coupled in series with the driving resistor 213b, and the second capacitor 220b is electrically coupled in antiparallel with the gate-source of the switch Q2, so the voltage Vgs_2(t) of the gate-source of the switch Q2 is clamped at a low negative voltage value. The gate-source of the switch Q2 realizes the negative voltage turn-off, and the second capacitor 220b and the driving resistor 213b are turned off in sequence.

During the period from time t5 to t6, the driving signal PWM1 of the driving system 1a changes from low level to high level, the driving pulse U_H1 changes from high impedance to high level, and the driving pulse U_L1 changes from low level to high impedance. The bootstrap capacitor Cboot supplies power to the driver chip 50a for providing a forward conduction voltage for the gate-source of the switch Q1, and the voltage of the gate-source of the switch Q1 is raised. The switch Q1 is turned on when the gate-source voltage of the switch Q1 reaches the driving threshold voltage of the switch Q1. Meanwhile, the conduction path is the driving resistor 212a, the first capacitor 210a and the second capacitor 220a in sequence. The driving resistor 212a, the first capacitor 210a and the second capacitor 220a realize a rapid voltage division for ensuring that the gate-source voltage of the switch Q1 does not exceed the clamping voltage value. Simultaneously, the second capacitor 220a is rapidly charged to store charge for realizing a negative voltage turn off of the switch Q1. The driving signal PWM2 of the driving system 1b maintains a low level, the driving pulse U_H2 maintains a high impedance, the driving pulse U_L2 maintains a low level, the voltage of the second capacitor 220b ensures that the gate-source of the switch Q2 realizes a negative voltage turn-off, and the switch Q2 remains in the off state.

During the period from time t6 to t7, the driving circuit for the GaN device is in a stable state, and the switching states of the switches Q1 and Q2 are remained. The driving signal PWM1 of the driving system 1a maintains a high level, the driving pulse U_H1 maintains a high level, and the driving pulse U_L1 maintains a high impedance. Meanwhile, the first resistor 211a consumes the charge stored in the first capacitor 210a. Therefore, the current flows through the drive resistor 212a, the first resistor 211a, the first Zener diode 221a, the second Zener diode 230a and the third Zener diode 231a in sequence. The switch Q1 remains in the on state. The driving signal PWM2 of the driving system 1b maintains a low level, the driving pulse U_H2 maintains a high impedance, and the driving pulse U_L2 maintains a low level. Meanwhile, the voltage of the second capacitor 220b ensures that the gate-source of the switch Q2 realizes a negative voltage turn-off, and the switch Q2 remains in the off state.

From the above descriptions, in the driving system for the switching device of the present disclosure, the high-impedance voltage dividing module performs voltage division and limiting on the driving voltage of the switching device when the switching device is turned on, thereby making the gate-source voltage of the switching device to be lower than the clamping voltage value. In addition, the constant voltage dividing module of the present disclosure provides a low-impedance shunt path for the gate-source of the switching device when the change rate of the drain-source voltage of the switching device is too high. Accordingly, the gate-source voltage of the switching device is controlled to be lower than the trigger threshold so that the false trigger of the switching device is avoided.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A driving system for driving at least one switching device, comprising:
at least one switch driving module receiving a driving signal and outputting a driving voltage according to the driving signal; and
at least one switching device electrically coupled to the at least one switch driving module, wherein the switching device receives the driving voltage, and the switching device is turned on or off according to the driving voltage,
wherein the switch driving module comprises:
a high-impedance voltage dividing module, wherein the high-impedance voltage dividing module is configured for dividing and limiting the driving voltage of the switching device when the switching device is turned on, thereby making a gate-source voltage of the switching device to be lower than a clamping voltage value; and
a constant voltage dividing module electrically coupled to the high-impedance voltage dividing module, wherein when the switching device is turned off and the changing rate of a drain-source voltage of the switching device is too high, the constant voltage dividing module provides a low-impedance shunt path for the gate-source of the switching device to make the gate-source voltage of the switching device to be lower than a trigger threshold.

2. The driving system according to claim 1, further comprising:
a control module configured for outputting a control signal; and
a driving pulse generating module electrically coupled to the control module and the switch driving module, wherein the driving pulse generating module receives the control signal and outputs the driving signal to the switch driving module according to the control signal.

3. The driving system according to claim 2, wherein the driving pulse generating module comprises a driving chip which receives the control signal and outputs the driving signal.

4. The driving system according to claim 3, wherein the high-impedance voltage dividing module comprises a first capacitor and a first resistor electrically coupled in parallel, a first terminal of the first capacitor and a first terminal of the first resistor are both electrically coupled to a first node, a second terminal of the first capacitor and a second terminal of the first resistor are both electrically coupled to a second node, the first node and the second node are electrically coupled to the driving chip through two driving resistors respectively.

5. The driving system according to claim 4, wherein the first node is electrically coupled to a first output terminal of the driving chip, and the second node is electrically coupled to a second output terminal of the driving chip,
wherein the voltage level of the first output terminal is higher than that of the second output terminal.

6. The driving system according to claim 3, wherein the high-impedance voltage dividing module comprises a first capacitor, a first resistor and a first driving resistor, a first terminal of the first capacitor is electrically coupled to a first node through the first driving resistor, and a first terminal of the first resistor is electrically coupled to the first node, a second terminal of the first capacitor and a second terminal of the first resistor are both electrically coupled to a second node, the first node is electrically coupled to a first output terminal of the driving chip and the second node is electrically coupled to a second output terminal of the driving chip through a second driving resistor.

7. The driving system according to claim 6, wherein the voltage level of the first output terminal is higher than that of the second output terminal.

8. The driving system according to claim 1, wherein the constant voltage dividing module comprises a second capacitor and a first Zener diode electrically coupled in parallel, a first terminal of the second capacitor and a cathode of the first Zener diode are electrically coupled to the high-impedance voltage dividing module, a second terminal of the second capacitor and an anode of the first Zener diode are electrically coupled to a gate of the switching device.

9. The driving system according to claim 8, wherein a capacitance of the first capacitor of the high-impedance voltage dividing module is lower than a capacitance of the second capacitor of the constant voltage dividing module.

10. The driving system according to claim 1, wherein the switch driving module further comprises a voltage clamping module electrically coupled to the constant voltage dividing module and a source of the switching device and configured for clamping the gate-source voltage of the switching device.

11. The driving system according to claim 10, wherein the voltage clamping module comprises a second Zener diode and a third Zener diode electrically coupled in series, an anode of the second Zener diode is electrically coupled to an anode of the third Zener diode, a cathode of the second Zener diode is electrically coupled to a gate of the switching device, a cathode of the third Zener diode is electrically coupled to the source of the switching device.

12. The driving system according to claim 1, wherein when the switching device is turned off, the constant voltage dividing module clamps the gate-source voltage of the switching device to a low constant negative voltage value for providing a turn-off path for the switching device and reducing the reverse conduction voltage of the switching device.

13. The driving system according to claim 1, wherein the switching device is a GaN device.

14. The driving system according to claim 1, wherein the at least one switching device comprises a first switching device and a second switching device, wherein the first switching device and the second switching device are electrically coupled in series to form a half-bridge switching circuit.

15. A driving system for driving at least one switching device, comprising:
at least one switch driving module receiving a driving signal and outputting a driving voltage according to the driving signal; and
at least one switching device electrically coupled to the at least one switch driving module, wherein the switching device receives the driving voltage, and the switching device is turned on or off according to the driving voltage,
wherein the switch driving module comprises:
a high-impedance voltage dividing module, wherein the high-impedance voltage dividing module is configured for dividing and limiting the driving voltage of the switching device when the switching device is turned on, thereby making a gate-source voltage of the switching device to be lower than a clamping voltage value; and
a constant voltage dividing module electrically coupled to the high-impedance voltage dividing module, wherein when the switching device is turned off, the constant voltage dividing module clamps the gate-source voltage of the switching device to a low constant negative voltage value for providing a turn-off path for the switching device and reducing the reverse conduction voltage of the switching device.

16. The driving system according to claim 15, wherein the switch driving module further comprises a voltage clamping module electrically coupled to the constant voltage dividing module and a source of the switching device and configured for clamping the gate-source voltage of the switching device.

17. The driving system according to claim 15, further comprising:
a control module configured for outputting a control signal; and
a driving pulse generating module electrically coupled to the control module and the switch driving module, wherein the driving pulse generating module comprises a driving chip which receives the control signal and outputs the driving signal to the switch driving module according to the control signal.

18. The driving system according to claim 17, wherein the high-impedance voltage dividing module comprises a first capacitor and a first resistor electrically coupled in parallel, a first terminal of the first capacitor and a first terminal of the first resistor are both electrically coupled to a first node, a second terminal of the first capacitor and a second terminal of the first resistor are both electrically coupled to a second node, the first node and the second node are electrically coupled to the driving chip through two driving resistors respectively.

19. The driving system according to claim 17, wherein the high-impedance voltage dividing module comprises a first capacitor, a first resistor and a first driving resistor, a first terminal of the first capacitor is electrically coupled to a first node through the first driving resistor, and a first terminal of the first resistor is electrically coupled to the first node, a second terminal of the first capacitor and a second terminal of the first resistor are both electrically coupled to a second node, the first node is electrically coupled to a first output terminal of the driving chip and the second node is electrically coupled to a second output terminal of the driving chip through a second driving resistor.

20. The driving system according to claim 17, wherein the constant voltage dividing module comprises a second capacitor and a first Zener diode electrically coupled in parallel, a first terminal of the second capacitor and a cathode of the first Zener diode are electrically coupled to the high-impedance voltage dividing module, a second terminal of the second capacitor and an anode of the first Zener diode are electrically coupled to a gate of the switching device.
